(19) United States
(12) Patent Application Publication
(10) Pub. No.: US 2011/0133340 A1
(43) Pub. Date: Jun. 9, 2011

(54) Package substrate and semiconductor apparatus

(75) Inventor: Ryuichi OIKAWA, Kanagawa (JP)

(73) Assignee: Renesas Electronics Corporation, Kawasaki (JP)

(21) Appl. No.: 12/926,640

(22) Filed: Dec. 1, 2010

(30) Foreign Application Priority Data
Dec. 3, 2009 (JP) 2009-275835

(51) Int. Cl. H01L 23/522; H05K 1/11

(52) U.S. Cl. 257/773; 174/262; 257/E23.142

(57) ABSTRACT

A package substrate includes: a plurality of electrodes configured to be electrically connected to a semiconductor chip; a plurality of wiring layers configured to be stacked; and a plurality of vias configured to electrically connect a plurality of planes formed in the plurality of wiring layers. A power supply via included in the plurality of vias electrically connects a power supply plane included in the plurality of planes to a power supply electrode included in the plurality of electrodes. The power supply plane is supplied with a power supply voltage. A passing wiring layer included in the plurality of wiring layers, through which the power supply via passes, includes: grid ground planes configured to surround the power supply via. The grid ground planes are electrically connected to a ground plane included in the plurality of planes through a ground via included in the plurality of vias. The ground plane is grounded.

### INCORPORATION BY REFERENCE

This application is based upon and claims the benefit of priority from Japanese patent application No. 2009-275835 filed on Dec. 3, 2009, the disclosure of which is incorporated herein in its entirety by reference.

### BACKGROUND OF THE INVENTION

1. Field of the Invention

The present invention relates to a package substrate and a semiconductor apparatus. More particularly, the present invention relates to a package substrate and a semiconductor apparatus including a coreless multi-layer wiring substrate.

2. Description of Related Art

As a speeding-up of an LSI (Large-Scale Integration), an increase of a signal pin and a decrease of a voltage for reducing electric power consumption, a malfunction caused by the power supply noise has become a serious problem. Especially, in the LSI which is classified into so-called high-end, a designing of a semiconductor chip (Si), a package and a board in concurrently is becoming mainstream to suppress power supply noise within an acceptable range. It is a critical problem, even with a package substrate design, how to restrain power supply noise to an appropriate amount.

The Effects of the signal speed increase, the increase of the signal pin and the decrease of the voltage on the package design are described as follows.

The first effect is that, as the signal speed increases, a time change rate of a switching electric current which an inner device of the LSI draws out from or supplies to the power supply or the ground increases. This current flows into the LSI from the power supply of the LSI package (or flows out from the LSI to the power supply of the LSI package). In this case, the power supply noise (the counter electromotive force) Vn generated by the parasitic (power supply) inductance L of the LSI package is represented by the following formula using the current I and the time t.

Vn=−L·dI/dt (1)

As shown in the formula (1), the power supply noise increases as the signal speed increases. Actually, adding a capacitor on the semiconductor chip makes the time change rate of the electric current flowing into the LSI package lower. However, it is not preferable because this leads to a cost increase due to the chip area consumption and an internal delay increase. As shown in the formula (1), in order to suppress the power supply noise within an acceptable range without relying on the means of the semiconductor chip design, it is necessary to reduce the power supply inductance (power supply impedance if angular frequency is multiplied) of the LSI package so that its value is roughly inversely proportional to the signal speed.

The second effect is that, as the increase of the signal pin, there is a problem of the SSN (Simultaneous Switching Noise) caused by the SSO (Simultaneous Switching Output). If all the N signal lines are switched on or off simultaneously, the switching electric current is as large as N times as that from single signal line, which is represented by the following formula (2) by referring to the formula (1).

Vn=−N·L·dI/dt (2)

Therefore, the generated power supply noise is N times larger than that from single signal line. Therefore, in order to suppress the power supply noise within an appropriate range without relying on the means on the semiconductor chip, it is again necessary to reduce the power supply impedance of the LSI package roughly inversely proportionally to the number of the signal pins.

The third effect is related to the decrease of the voltage. In order to avoid the malfunction of the LSI circuit, a variation of the power supply voltage must reside within a certain range which is referred as an operation margin. In the case of lowering the power supply voltage, it is necessary to reduce the threshold voltage of a transistor. Therefore, generally, the operation margin proportionally decreases to the power supply voltage. For example, let us assume that the operation margin is 5% of the power supply voltage. In this case, if the power supply voltage is 2.0 V, the operation margin is 100 mV. However, if the power supply voltage becomes 1.0 V, the operation margin becomes 50 mV. Therefore, furthermore, it is necessary to reduce the power supply impedance of the LSI package roughly inversely proportionally to the power supply voltage. Consequently, in order to suppress afore mentioned three effects, i.e., signal speed increase, the increase of the signal pin and the decrease of the power supply voltage, it is necessary to reduce the power supply impedance of the LSI package inversely proportionally to the value defined by the following formula.

(the signal speed)×(the number of signal pins)/(the power supply voltage)

According to the above formula, the power supply impedance must be even more significantly reduced to gain enough operation margin of the LSI. Therefore, how to reduce the power supply impedance of the LSI package is one of the critical problems in the LSI industry.

However, it is difficult to reduce the impedance of the power supply system of the LSI package because of layout space restriction, especially when there are a lot of signals routed inside the LSI package. That is, if a large area in a layout space inside the package is used for the power supply system, signal line routing space runs short. This often leads to the interference among signals and the mismatch of the transmission line impedance, thereby resulting the degradation of a signal waveform. In the first place, the original purpose of reducing the power supply impedance is to avoid the signal waveform degradation caused by the voltage variation or power supply noise generated by the LSI operation. Thus, this is against the initial objectives.

On the contrary, if a large area in a layout space inside the package is used for the placement of signal lines to decrease the interference among signals and the mismatch of the transmission line impedance, an area for the power supply system runs short. This often leads to the increase of the power supply noise, thereby resulting the degradation of a signal waveform. As shown above, in the LSI package with high speed signals and many signal pins, there is a trade-off relation between signal lines and power supply system for the layout resource. As a result, it has been becoming more and more difficult to achieve stable and optimized LSI operation.

As a related art, Japanese Patent Publication No. JP-P 2000-188478(A1) (corresponding to U.S. Pat. No. 6,392,164(B1)), discloses a multilayer circuit board in which a substrate structure used for a characteristic impedance matching is miniaturized. The multilayer circuit board includes: at least two wiring layers arranged so as to be faced; insulating layers formed between the wiring layers; a connecting body formed so as to pass through the insulating layers along the direction facing the wiring layer and connect the wiring layers; an intermediate connecting layer electrically connecting a part on one end and a part on the other end of the connecting body in a central position of the connecting body along the direction facing the wiring layer; and a shielding layer arranged on a face nearly identical to the intermediate connecting layer so as to be separated from a periphery of the intermediate connecting layer. A connecting, distance between the wiring layers via the connecting body and the intermediate connecting layer is designated as h. A diameter of the connecting body in the case the connecting body is regarded as a nearly cylindrical body is designated as R. A diameter of the intermediate connecting layer in the case the intermediate connecting layer is regarded as a nearly cylindrical shape is designated as r. A separation distance between the intermediate connecting layer and the shielding layer is designated as L. Then, when a condition of

(R·r)/(2·h)≦L≦(5·R·r)/h

is satisfied, the separation distance L between the intermediate connecting layer and the shielding layer is the optimum value.

Japanese Patent Publication JP-P 2005-064028(A1) discloses a multilayered wiring board that can reduce impedances of grounding through-hole conductors and power supply through-hole conductors to avoid performance degradation of a high-speed logic circuit of a electric signal circuit using the multilayered wiring board. In the wiring board: metallic conductive layers and dielectric layers are alternately stacked on both a first main surface and a second main surface of a plate-shaped metallic core; at least one of the conductive layers is a power supply layer and at least another of the conductive layers is a ground layer; a core penetration hole is formed in the plate-shaped metallic core; 2 or more through-hole conductors, which connects a conductor of the first main surface side and a conductor of the second main surface side so as to be spatially separated from each other and from the plate-shape metallic core by dielectric material filling the core penetration hole, are placed in the core penetration hole; at least one of the through-hole conductors is a power supply through-hole conductor conducting the power supply layer; and at least another of the through-hole conductors is a ground through-hole conductor conducting the ground layer.

Japanese Patent Publication JP-A-Heisei 06-085099 discloses a signal circuit of high frequency circuit board. The signal circuit of high frequency circuit board includes: a substrate made by laminating a plurality of dielectric layers; a via formed so as to continuously pass through the dielectric layers; and ground planes sandwiched between the dielectric layers around the via so as to surround the via; wherein the via is made to be a pseudo coaxial line structure, and a signal line is connected to the via having a pseudo coaxial line structure. In the signal circuit of high frequency circuit board, a plurality of ground vias connected to the ground plane, which surrounds the via, in a dielectric layer above a topmost ground plane between the dielectric layers or a dielectric layer below a undermost ground plane between the dielectric layers, thereby providing the via formed in the dielectric layer above the topmost ground plane or the via formed in the dielectric layer below the undermost ground plane between the dielectric layers as the pseudo coaxial line structure.

The publication of “Electrical Design Methodology for the over 20 Metal Layer PALAP FCBGA Substrate for the High-Speed Low-Power/Ground Noise Application and its Electrical Performance” in Proceedings of 39th international symposium on microelectronics, 1148(2006) written by R. Oikawa and K. Suzuki discloses an example for reducing the power supply impedance by using a coreless and multilayer substrate made of thermoplastic resin. In this example, by preparing 20 or more metal layers available for wiring, power supply and ground, while enough signal layout space can be secured for the multi-signal system, a large layout space is reserved for the power supply system. As a result, in this example, compared to such as build-up substrates with a core layer, the impedance of the power supply system especially in the many signal system is drastically reduced.

The inventor has now discovered the following facts.

The JP-P2005-064028(A1) discloses a multilayered wiring board that a through-hole for the power supply and a through-hole for the ground are adjacently arranged and the impedance of the through-holes is reduced due to mutual inductance. This is the principle of the generally well known differential signaling. Since the phase of the current of the power supply is approximately opposite to the phase of the current of the ground, the phase of the magnetic field of the power supply becomes also approximately opposite to the phase of the magnetic field of the ground. Therefore, the magnetic field of the power supply through-hole and the magnetic field of the ground through-hole are negated by each other, and consequently the effective impedance (to be exact, the loop impedance) is reduced. In other words, the effective impedance is reduced by the amount of the mutual impedance. Since the power supply through-hole and the ground through-hole are both always necessary, the impedance of the power supply system is reduced without need for an additional layout space.

Generally speaking, in the typical LSI package substrate, it is practically and geometrically impossible not to adjacently arrange the power supply through-holes and the ground through-holes. Therefore, the typical structure of the package substrate is such that the power supply through-holes and the ground through-holes are alternately arranged in a surrounding space of the signal through-hole or an empty space.

Further, as shown in the above-mentioned document of Proceedings of 39th international symposium on microelectronics, 1148 (2006), there is the example for reducing the power supply impedance by using a coreless and multilayer substrate made of thermoplastic resin. In this example, by preparing 20 or more metal layers available for wiring signal, power supply and ground, enough layout space is secured for both signal and power supply system even in a system with large number of signals. As a result, in this example, as compared to such as build-up substrates with a core layer, the impedance of the power supply system especially in the many signal system is drastically reduced. However, even though the coreless and multilayer substrate is used, it is not always achieved a sufficiently-low power supply impedance.

FIGS. 1 to 3 shows an example that the FCBGA (flip-chip BGA) package substrate is applied to the multi-signal semiconductor chip using a so-called area I/O formed inner-side of a Si die in addition to a peripheral I/O.

FIG. 1 shows electrodes arranged on the package substrate of the example. The electrodes 106 includes peripheral ground electrodes 121, peripheral power supply electrodes 122, peripheral signal electrodes 123, area power supply electrodes 124, area signal electrodes 125 and area ground electrodes 120. A surface where the electrodes 106 of the package substrate are arranged is in a mounting area for a semiconductor chip and includes a peripheral I/O region 111 and an area I/O region 112. In the peripheral I/O region 111, the peripheral ground electrodes 121, the peripheral power supply electrodes 122 and the peripheral signal electrodes 123 are arranged. In the area I/O region 112, the area power supply electrodes 124, the area signal electrodes 125 and the area ground electrodes 120 are arranged. The area I/O region 112 is arranged adjacently to the peripheral I/O region 111 on the side of the center of the package substrate (a direction 115, to the semiconductor chip center) as compared with the peripheral I/O region 111. That is, in FIG. 1, since only a part of the surface where the electrodes 106 of the package substrate are arranged is shown, the peripheral I/O region 111 and the area I/O region 112 are placed in one direction. However, actually, the peripheral I/O region 111 is arranged so as to surrounds the area I/O region 112.

The peripheral I/O region 111 includes a peripheral ground area 126, a peripheral power supply area 127 and a peripheral signal area 128. In the peripheral ground area 126, the peripheral ground electrodes 121 are arranged in line. In the peripheral power supply area 127, the peripheral power supply electrodes 122 are arranged in line. In the peripheral signal area 128, the peripheral signal electrodes 123 are arranged. The peripheral ground area 126 is arranged on the side of the edge of the package substrate in the peripheral I/O region 111 (a direction 114, to the semiconductor chip edge). The peripheral power supply area 127 is arranged on the side of the center of the package substrate in the peripheral I/O region 111. The peripheral signal area 128 is arranged adjacently to the peripheral ground area 126 on the side of the semiconductor chip center direction 115 against the peripheral ground area 126. The peripheral signal area 128 is arranged adjacently to the peripheral power supply area 127 on the side of the direction opposite to the semiconductor chip center direction 115. That is, the peripheral ground area 126 is arranged so as to surround the peripheral signal area 128, and the peripheral signal area 128 is arranged so as to surround the peripheral power supply area 127. The peripheral signal area 128 is arranged between the peripheral ground area 126 and the peripheral power supply area 127.

The area I/O region 112 includes an area power supply ground area 129 and an area signal region 130. In the area power supply ground area 129, the area ground electrodes 120 and the area power supply electrodes 124 are arranged. In the area signal region 130, the area signal electrodes 125 are arranged. The area power electrodes 124 and the area ground electrodes 120 are arranged in line in the area power supply ground area 129 such that the area power electrodes 124 are not arranged adjacently to each other, the area ground electrodes 120 are not arranged adjacently to each other and one area power supply electrode 124 and one area ground electrode 120 are arranged adjacently to each other. That is, the area power supply electrodes 124 and the area ground electrodes 120 are alternately arranged in line. The area power supply ground area 129 is arranged on the side of the edge of the semiconductor chip center direction 115 in the area I/O region 112. The area signal region 130 is arranged adjacently to the area power supply ground area 129 on the side of the direction opposite to the semiconductor chip center direction 115 against the area power supply ground area 129. That is, the area signal region 130 is arranged so as to surround the area power supply ground area 129.

FIG. 2 shows the package substrate. The package substrate 102 is formed such that a plurality of wiring layers 131-1 to 131-n is stacked. Each of the plurality of wiring layers 131-1 to 131-n is formed using a plurality of wiring planes made of conductive material such as metal. Adjacent two of the plurality of wiring layers are insulated from each other by an insulating layer sandwiched therebetween. The plurality of wiring planes includes peripheral power supply planes 132, ground planes 133, area power supply planes 134, logic power supply planes 135 and signal planes 136. To the peripheral power supply planes 132, a power supply voltage is applied through a printed board. The ground planes 133 are grounded through the printed circuit board. To the area power supply planes 134, the power supply voltage is applied through the printed circuit board. To the logic power supply planes 135, the power supply voltage is applied through the printed circuit board. The signal planes 136 are electrically connected to signal lines of the printed circuit board.

The package substrate 102 includes a plurality of vias. Each via is formed of conductive material and electrically connects a part of a wiring plane in one wiring layer 131-i (i=1, 2, 3, . . . , n) of the plurality of wiring layers 131-1 to 131-n to a part of a wiring plane in another wiring layer 131-(i-1) adjacent to the wiring layer 131-i. The plurality of vias includes peripheral power supply vias 141, peripheral signal vias 142, area signal vias 143, area power supply vias 144 and area ground vias (described later). The peripheral power supply via 141 is arranged so as to electrically connect the peripheral power supply electrode 122 to the peripheral power supply plane 132 in a linear manner. The peripheral signal via 142 is arranged so as to electrically connect the peripheral signal electrode 123 to the signal plane 136 in a linear manner. The area signal via 143 is arranged so as to electrically connect the area signal electrode 125 to the signal plane 136 in a linear manner. The area power supply via 144 is arranged so as to electrically connect the area power supply electrode 124 to the area power supply plane 134 in a linear manner. In this case, the peripheral power supply via 141, the peripheral signal via 142, the area signal via 143 and the area power supply via 144 are arranged so that a straight line that the peripheral power supply via 141 is taken along, a straight line that the peripheral signal via 142 is taken along, a straight line that the area signal via 143 is taken along and a straight line that the area power supply via 144 is taken along are arranged so as to be parallel to each other.

FIG. 3 shows the area ground vias of the plurality of vias. The area ground via 145 is arranged so as to be approximately parallel to the area power supply via 144 and electrically connects the area ground electrode 120 to the ground plane 133. Further, the area ground vias 145 and the area power supply vias 144 are arranged so as to be included in single plane and alternately placed each other.

In the peripheral I/O region 111, the line of the peripheral power supply electrodes 122 and the line of the peripheral ground electrode 121 are arranged away from each other such that the group of the peripheral signal electrodes 123 are sandwiched between the line of the peripheral power supply electrodes 122 and the line of the peripheral ground electrode 121. However, this arrangement is a rare case. This is because the power and ground voltage drops become asymmetrical except at the I/O buffers that drives center signals. Generally, as shown in the area I/O region 112, the power supply electrodes and the ground electrodes are alternately arranged one another, or the line of the power supply electrodes and the line of the ground electrodes are adjacently arranged each other. The C4 electrodes of these power supply and ground are connected to the lower layer power supply and ground plane through via holes. Therefore, the via holes of the power supply and ground are adjacently arranged each other, reflecting the arrangement of the C4 electrodes. Since a direction of a magnetic field of the via holes of the power supply is oppose to a direction of a magnetic field of the via holes of the ground, an effective inductance is reduced.

As shown in this example, there is a problem in the case that signal pins are densely arranged both the peripheral I/O region 111 and the area I/O region 112. Since the signal pins are densely arranged throughout the multi-layers, it is difficult to take enough space for arranging the power supply planes in the upper side (near the die) of the FCBGA substrate, in the area I/O region 112. As shown in FIG. 2, the case occurs in which the area power supply electrode 124 of the area I/O region 112 is connected to the power supply plane 134 only at the very lower layer, namely, the layer much away from the silicon die. In this case, due to the large distance from the die to the power supply plane 134, the power supply impedance tends to be high in the area I/O region 112. Even though the impedance is reduced by adjacently arranging the area power supply vias 144 and the area ground vias 145, the effect of this arrangement is not enough in some cases. Actually, in the case of adjacently arranged power supply vias and the ground vias, the space for placing the power supply vias is reduced because of the space where the ground vias are already placed. Therefore, the impedance reduction effect and impedance increase effect cancel each other, thus significant effect is not obtained.

FIG. 4A shows a measurement result of the impedance of the area power supply vias 144 in this example. The measurement result 161 shows that the impedance of the area power supply vias varies widely. FIG. 4B shows a measurement result of the impedance of the peripheral power supply vias 141 in this example. The measurement result 162 shows that the impedance of the peripheral power supply vias varies widely. By comparing the measurement result 161 to 162, it is clear that the impedance of the area power supply vias 144 is more than twice larger than that of the peripheral power supply vias 141.

The objective of the present invention is to provide the way to reduce the power supply impedance of the LSI device at the same time preserving enough layout space for high density signals.

### SUMMARY

The present invention seeks to solve one or more of the above problems, or to improve upon those problems at least in part.

In one embodiment, a package substrate includes: a plurality of electrodes configured to be electrically connected to a semiconductor chip; a plurality of wiring layers configured to be stacked; and a plurality of vias configured to electrically connect a plurality of planes formed in the plurality of wiring layers, wherein a power supply via included in the plurality of vias electrically connects a power supply plane included in the plurality of planes to a power supply electrode included in the plurality of electrodes, the power supply plane being supplied with a power supply voltage, wherein a passing wiring layer included in the plurality of wiring layers, through which the power supply via passes, includes: grid ground planes configured to surround the power supply via, and wherein the grid ground planes are electrically connected to a ground plane included in the plurality of planes through a ground via included in the plurality of vias, the ground plane being grounded.

In another embodiment, a package substrate includes: a plurality of electrodes configured to be electrically connected to a semiconductor chip; a plurality of wiring layers configured to be stacked; and a plurality of vias configured to electrically connect a plurality of planes formed in the plurality of wiring layers, wherein a ground via included in the plurality of vias electrically connects a ground plane included in the plurality of planes to a ground electrode included in the plurality of electrodes, the ground plane being grounded, wherein a passing wiring layer included in the plurality of wiring layers, through which the ground via passes, includes: grid power supply planes configured to surround the ground via, and wherein the grid power supply planes are electrically connected to a power supply plane included in the plurality of planes through a power supply via included in the plurality of vias, the power supply plane being supplied with a power supply voltage.

In still another embodiment, a semiconductor apparatus includes: a semiconductor chip; and a package substrate configured to be electrically connected to the semiconductor chip, wherein the package substrate includes: a plurality of electrodes configured to be electrically connected to the semiconductor chip; a plurality of wiring layers configured to be stacked; and a plurality of vias configured to electrically connect a plurality of planes formed in the plurality of wiring layers, wherein a power supply via included in the plurality of vias electrically connects a power supply plane included in the plurality of planes to a power supply electrode included in the plurality of electrodes, the power supply plane being supplied with a power supply voltage, wherein a passing wiring layer included in the plurality of wiring layers, through which the power supply via passes, includes: grid ground planes configured to surround the power supply via, wherein the grid ground planes are electrically connected to a ground plane included in the plurality of planes through a ground via included in the plurality of vias, the ground plane being grounded.

In yet still another embodiment, a semiconductor apparatus includes: a semiconductor chip; and a package substrate configured to be electrically connected to the semiconductor chip, wherein the package substrate includes: a plurality of electrodes configured to be electrically connected to the semiconductor chip; a plurality of wiring layers configured to be stacked; and a plurality of vias configured to electrically connect a plurality of planes formed in the plurality of wiring layers, wherein a ground via included in the plurality of vias electrically connects a ground plane included in the plurality of planes to a ground electrode included in the plurality of electrodes, the ground plane being grounded, wherein a passing wiring layer included in the plurality of wiring layers, through which the ground via passes, includes: grid power supply planes configured to surround the ground via, and wherein the grid power supply planes are electrically connected to a power supply plane included in the plurality of planes through a power supply via included in the plurality of vias, the power supply plane being supplied with a power supply voltage.

The package substrate of the present invention generates a strong mutual inductance between the power supply via and a grid pattern. Therefore, the effective impedance of the power supply via is reduced and thus the power supply noise is reduced. Further, in the package substrate of the present invention, the increase of the layout space for the power supply system and the ground system is relatively small. Therefore, the layout space (e.g., layout resources for signals) other than the power supply system and the ground system is enough secured.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a plane view showing plural electrode arrangement on a conventional package substrate;

FIG. 2 is a sectional view showing the conventional package substrate;

FIG. 3 is a plane view showing an example of electrode arrangement of the conventional package substrate;

FIG. 4A is a graph showing a measurement result of an impedance of an area power supply via in a conventional semiconductor apparatus;

FIG. 4B is a graph showing a measurement result of an impedance of a peripheral power supply via in the conventional semiconductor apparatus;

FIG. 5 is a sectional view showing a semiconductor apparatus according to an embodiment of the present invention;

FIG. 6 is a plane view showing plural electrode arrangement of a package substrate according to the embodiment of the present invention;

FIG. 7 is a sectional view of the package substrate according to the embodiment of the present invention;

FIG. 8 is a plane view showing area power supply vias and a grid area ground pattern in a power supply wiring layer of the package substrate according to the present invention;

FIG. 9 is a plane view showing area power supply vias and a grid area ground pattern in a ground wiring layer of the package substrate according to the present invention;

FIG. 10A is a graph showing a measurement result of an impedance of the area power supply via of the semiconductor apparatus according to the embodiment of the present invention; and

FIG. 10B is a graph showing a measurement result of an impedance of the peripheral power supply via of the semiconductor apparatus according to the embodiment of the present invention.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

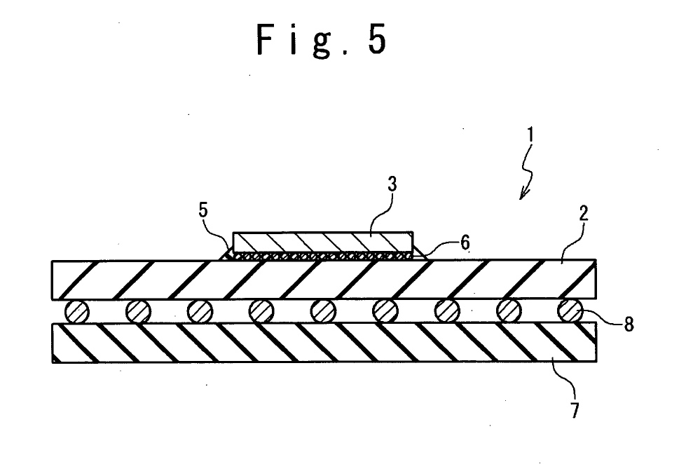

Embodiments of a semiconductor apparatus according to an embodiment of the present invention will be described below with reference to the attached drawings. As shown in FIG. 5, the semiconductor apparatus 1 includes a package substrate 2, a semiconductor chip 3, resin 5 and a plurality of bumps 6.

The package substrate 2 is formed into a plate and includes a plurality of electrodes on a surface of the side of the semiconductor chip 3. The semiconductor chip 3 includes a plurality of circuit elements and a plurality of bonding pads. The semiconductor chip 3 generates output electric signals based on input electric signals supplied through some of the plurality of bonding pads and outputs the output electric signals through some of the plurality of bonding pads outside. The bump 6 is formed of conductive material and electrically connects one of the plurality of bonding pads of the semiconductor chip 3 to one of the plurality of electrodes of the package substrate 2. The resin 5 is formed of resin which is insulating material. The space between the semiconductor chip 3 and the package substrate 2, where the bumps 6 are provided, is fully filled with the resin 5.

The semiconductor apparatus 1 is used while being mounted on a printed circuit board 7. That is, the printed circuit board 7 includes a plurality of ball lands (not shown). The plurality of ball lands is arranged so as to be exposed on a surface of the printed circuit board 7 of the side of the semiconductor apparatus 1. The package substrate 2 further includes a plurality of ball lands (not shown) on a surface of the side of the printed circuit board 7. In the semiconductor apparatus 1, one of the plurality of ball lands of the package substrate 2 is electrically connected to one of the plurality of ball lands of the printed circuit board 7.

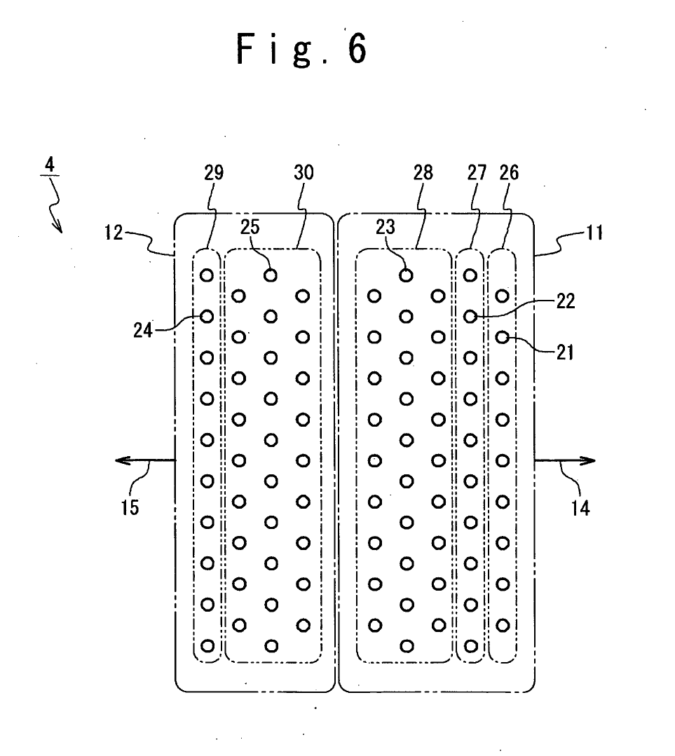

FIG. 6 shows electrodes 4 arranged on the package substrate 2. The electrodes 4 includes peripheral ground electrodes 21, peripheral power supply electrodes 22, peripheral signal electrodes 23, area power supply electrodes 24 and area signal electrodes 25. A surface where the electrodes 4 of the package substrate 2 are arranged is on the side of the semiconductor chip 3 and in amounting area for a semiconductor chip 3, and includes a peripheral I/O region 11 and an area I/O region 12. In the peripheral I/O region 11, the peripheral ground electrodes 21, the peripheral power supply electrodes 22 and the peripheral signal electrodes 23 are arranged. In the area I/O region 12, the area power supply electrodes 24 and the area signal electrodes 25 are arranged. The area I/O region 12 is arranged adjacently to the peripheral I/O region 11 on the side of the center of the package substrate 2 (a direction 15, to the semiconductor chip center) against the peripheral I/O region 11. That is, in FIG. 6, since only a part of the surface where the electrodes 4 of the package substrate 2 are arranged is shown, the peripheral I/O region 11 and the area I/O region 12 are placed in one direction. However, actually, the peripheral I/O region 11 is arranged so as to surrounds the area I/O region 12.

The peripheral I/O region 11 includes a peripheral ground area 26, a peripheral power supply area 27 and a peripheral signal area 28. In the peripheral ground area 26, the peripheral ground electrodes 21 are arranged in line. In the peripheral power supply area 27, the peripheral power supply electrodes 22 are arranged in line. In the peripheral signal area 28, the peripheral signal electrodes 23 are arranged. The peripheral ground area 26 is arranged on the side of the edge of the package substrate 2 in the peripheral I/O region 11 (a direction 14, to the semiconductor chip edge). The peripheral power supply area 27 is arranged adjacently to the peripheral ground area 26 on the side of the semiconductor chip center direction 15 against the peripheral ground area 26. The peripheral signal area 28 is arranged adjacently to the peripheral power supply area 27 on the side of the semiconductor chip center direction 15 against the peripheral power supply area 27 at the edge of the peripheral I/O region 11 in the semiconductor chip center direction 15. That is, the peripheral ground area 26 is arranged so as to surround the peripheral power supply area 27, and the peripheral power supply area 27 is arranged so as to surround the peripheral signal area 28.

The area I/O region 12 includes an area power supply area 29 and an area signal region 30. In the area power supply area 29, the area power supply electrodes 24 are arranged in line. In the area signal region 30, the area signal electrodes 25 are arranged. The area power supply area 29 is arranged on the side of the edge of the semiconductor chip center direction 15 in the area I/O region 12. The area signal region 30 is arranged adjacently to the area power supply area 29 on the side of the semiconductor chip's outer direction 14 against the area power supply area 29. That is, the area signal region 30 is arranged so as to surround the area power supply area 29.

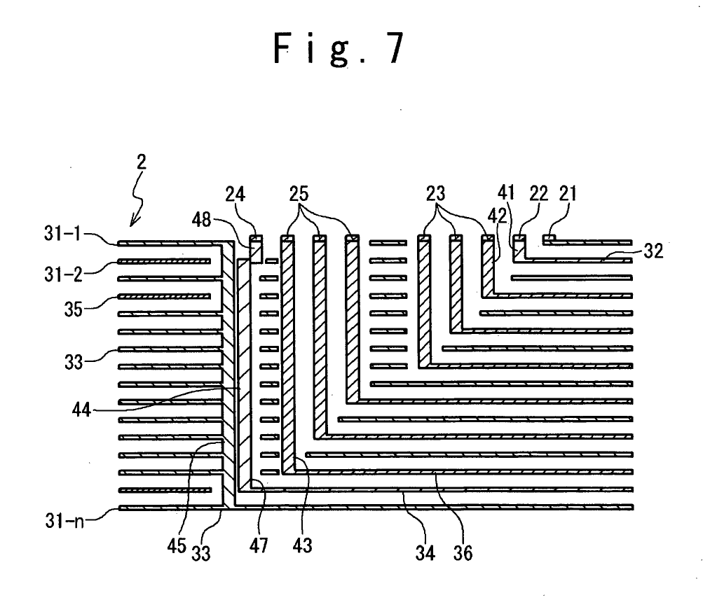

FIG. 7 shows a cross section of a part of the package substrate 2. The package substrate 2 is formed such that a plurality of wiring layers 31-1 to 31-n is stacked. Each of the plurality of wiring layers 31-1 to 31-n is formed using a plurality of wiring planes made of conductive material such as metal. Adjacent two of the plurality of wiring layers are insulated from each other by an insulating layer sandwiched therebetween. The plurality of wiring planes includes peripheral power supply planes 32, ground planes 33, lower part power supply planes 34, inside power supply planes 35 and signal planes 36. To the peripheral power supply planes 32, a power supply voltage is applied through the printed circuit board 7. The ground planes 33 are grounded through the printed circuit board 7. The lower part power supply planes 34 are formed in the wiring layer arranged on the side far from the semiconductor chip 3 compared to the wiring layer in which the signal planes 36 are formed. To the lower part power supply planes 34, the power supply voltage is applied through the printed circuit board 7. The inside power supply planes 35 are arranged on the side of the semiconductor chip center direction 15 against the peripheral power supply planes 32. To the inside power supply planes 35, the power supply voltage is applied through the printed circuit board 7. The signal layer 36 are electrically connected to the signal lines of the printed circuit board 7.

The package substrate 2 includes a plurality of vias. Each via is formed of conductive material and electrically connects a part of a wiring plane in one wiring layer 31-i (i=1, 2, 3, . . . , n) of the plurality of wiring layers 31-1 to 31-n to a part of a wiring plane in another wiring layer 31-(i-1) adjacent to the wiring layer 31-i. The plurality of vias includes peripheral power supply vias 41, peripheral signal vias 42, area signal vias 43, area power supply vias 44 and area ground vias 45. The peripheral power supply via 41 is arranged so as to electrically connect the peripheral power supply electrode 22 to the peripheral power supply plane 32 in a linear manner. The peripheral signal via 42 is arranged so as to electrically connect the peripheral signal electrode 23 to the signal layer 36 in a linear manner. The area signal via 43 is arranged so as to electrically connect the area signal electrode 25 to the signal layer 36 in a linear manner. The area power supply via 44 is arranged so as to electrically connect the area power supply electrode 24 to the lower part power supply plane 34 in a linear manner. The area ground via 45 is arranged so as to electrically connect the wiring layers, where the area ground vias 44 pass through, of the plurality of wiring layers 31-1 to 31-n in a linear manner. The area ground via 45 electrically connects the ground planes 33 to all of the grid ground planes (described later) formed in the plurality of wiring layers 31-1 to 31-n. In this case, the peripheral power supply via 41, the peripheral signal via 42, the area signal via 43, the area power supply via 44 and the area ground via 45 are arranged so that a straight line that the peripheral power supply via 41 is taken along, a straight line that the peripheral signal via 42 is taken along, a straight line that the area signal via 43 is taken along, a straight line that the area power supply via 44 is taken along and a straight line that the area ground via 45 is taken along are approximately parallel to each other.

In the package substrate 2, grid patterns are formed in the wiring layers, where the area power supply vias 44 are arranged, of the plurality of wiring layers 31-1 to 31-n.

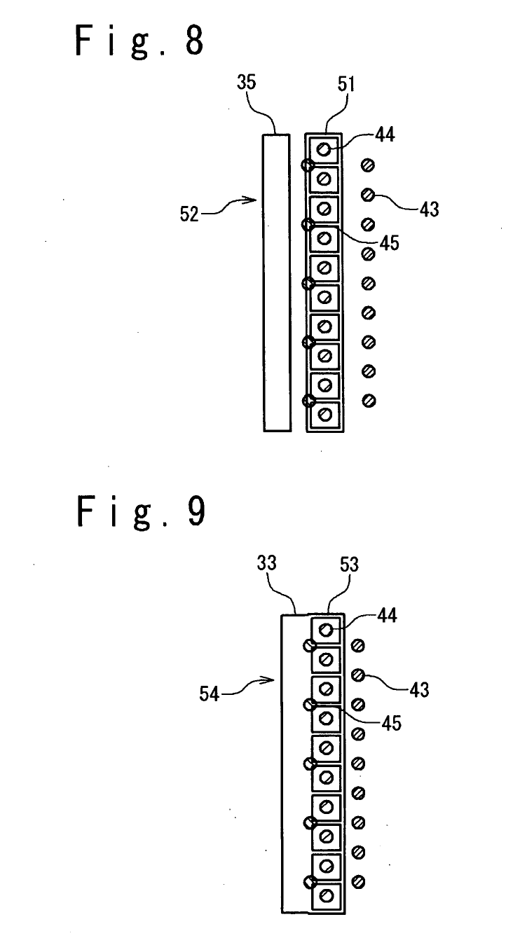

FIG. 8 shows a power supply wiring layer 52, where the inside power supply plane 35 is formed, of the plurality of wiring layers 31-1 to 31-n. In the power supply wiring layer 52, the grid ground plane 51 is formed. The grid ground plane 51 is formed so as to be electrically insulated from the area power supply vias 44 and surround each of the area power supply vias 44. That is, a part of the grid ground plane 51 is arranged between adjacent two of the area power supply vias 44. In addition, a part of the grid ground plane 51 is arranged between each area power supply via 44 and each area signal via 43. The grid ground plane 51 is further electrically insulated from the inside power supply plane 35. The grid ground plane 51 is electrically connected to the ground plane 33 through the area ground vias 45. There is no grid ground plane 51 between adjacent two of the plurality of the area signal vias 43. That is, the plurality of area signal vias 43 is arranged adjacently to each other without through any grid ground plane 51.

FIG. 9 shows a ground wiring layer 54 where the ground plane 33 of the plurality of wiring layer 31-1 to 31-n is formed. In the ground wiring layer 54, the grid ground plane 53 is formed. The grid ground plane 53 is arranged so as to be electrically insulated from the area power supply vias 44 and surround each of the area power supply vias 44. That is, a part of the grid ground plane 53 is arranged between adjacent two of the area power supply vias 44. In addition, a part of the grid ground plane 51 is arranged between each area power supply via 44 and each area signal via 43. The grid ground plane 53 is further electrically connected to the area ground vias 45 and the ground plane 33.

The area ground vias 45 electrically connect all of the grid ground planes 51 and all of the grid ground planes 53 to ground plane 33. The area ground vias 45, all of the grid ground planes 51 and all of the grid ground planes 53 are formed in the grid pattern surrounding the area power supply vias 44.

Since the area power supply vias 44 of the package substrate 2 are surrounded by the grid pattern, the area power supply vias 44 and the grid pattern have a strong mutual impedance and thus the effective impedance of the area power supply is drastically decreased. As a result, the power supply noise of the semiconductor apparatus 1 is reduced. In addition, since the area power supply electrodes 24 are arranged on the side of the semiconductor chip center direction 15 of the package substrate 2 as opposed to the area signal electrode 25, the semiconductor apparatus 1 can further sufficiently secure layout space for the multi-signal system.

In addition, there is no grid ground plane 51 between adjacent two of the plurality of the area signal vias 43 of the package substrate 2 and the plurality of area signal vias 43 is arranged adjacently to each other. Consequently, while an I/O size of a multi-signal macro and layout space of the package is saved, the area signal vias 43 can be collectively and densely arranged and the power supply impedance is reduced.

On the other hand, for example, in JP-A-Heisei 06-085099, the pseudo coaxial line structure is formed by providing the plurality of ground plane layers surrounding the signal via. Even though such a structure is suitable for high-speed signal transmission for a small number of signals, there is a difficulty in increasing a signal density without enlarging I/O macro size. Therefore, the invention of JP-A-Heisei 06-085099 is not effective as the present invention.

Incidentally, the area power supply vias 44 may not be arranged along a straight line. In this case, the area power supply vias 44 includes first area power supply vias 47 and second area power supply vias 48 as shown in FIG. 7. The first area power supply vias 47 are arranged so as to electrically connect the lower part power supply plane 34 to a part of the wiring layer 31-2 in a linear manner. The wiring layer 31-2 is a plane secondly nearest to the area power supply electrodes 24 in the plurality of wiring layers 31-1 to 31-n. The second area power supply vias 48 are electrically connected to the first area power supply vias 47 in the wiring layer 31-2. In addition, one end is electrically connected to the area power supply electrodes 24. Such area power supply vias 44 are employed when a pitch of the area power supply electrodes 24 is too small that a grid pattern cannot be formed in the wiring layer 31-1. Even the area power supply vias 44 have such structure, the area power supply vias 44 and the grid pattern have the strong mutual impedance and thus the effective impedance of the area power supply is drastically decreased. As a result, the power supply noise of the semiconductor apparatus 1 is reduced.

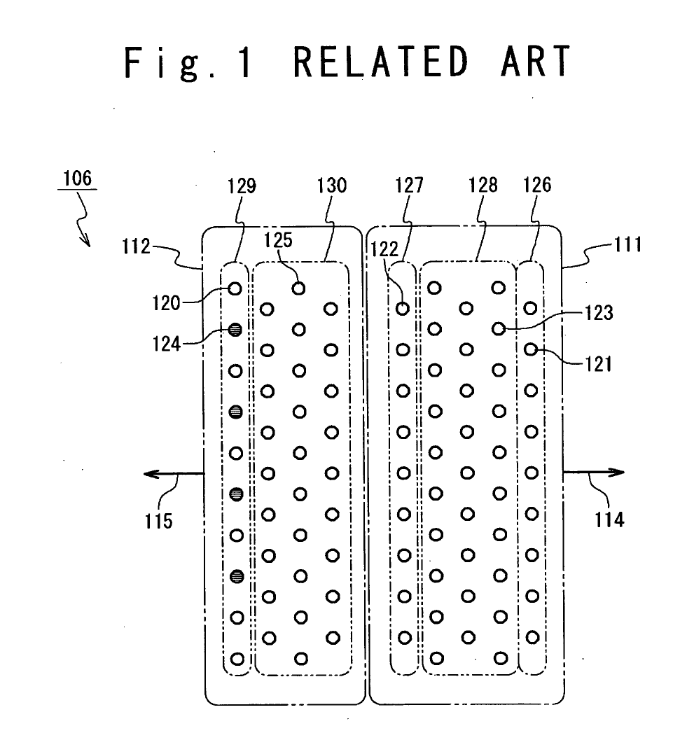

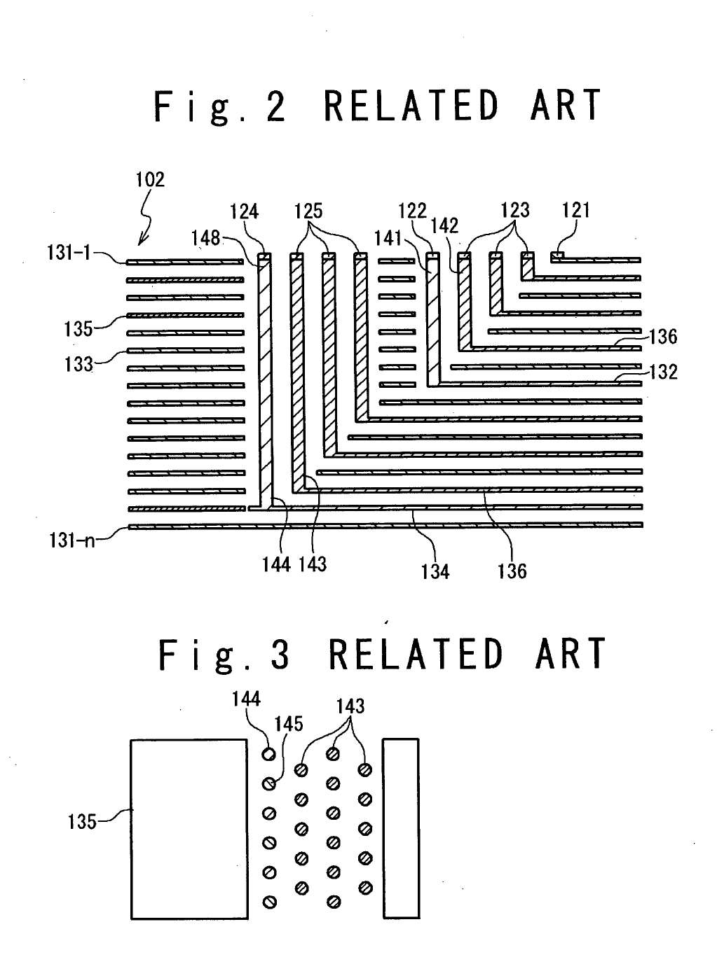

According to the three-dimensional electromagnetic field analysis, the semiconductor apparatus of the present invention that the grid ground planes surround the power supply via holes gives lower impedance than that of the semiconductor apparatus shown in FIGS. 1 to 3 that the power supply via holes and the ground via holes are alternately arranged. This is because, first the electromagnetic field between the via holes and the planes are very strong and secondly the space caused by the reduction of the ground via holes is used for the space of additional power supply via holes. The semiconductor apparatus according to the present invention, by optimizing the via hole - plane coupling, the number of the power supply via holes and the number of ground via holes by means of electromagnetic field analysis, provides a drastically lower impedance than that of the semiconductor apparatus shown in FIGS. 1 to 3.

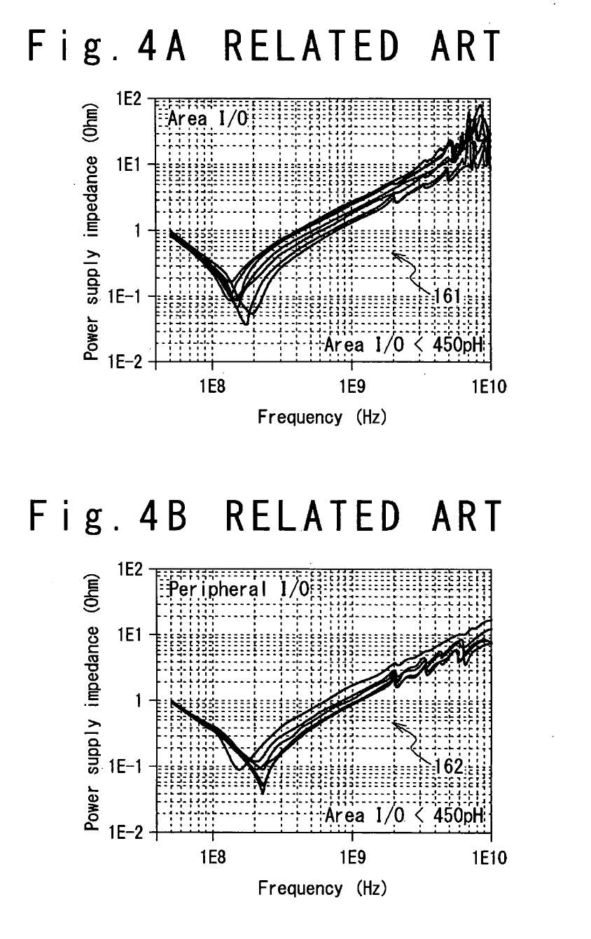

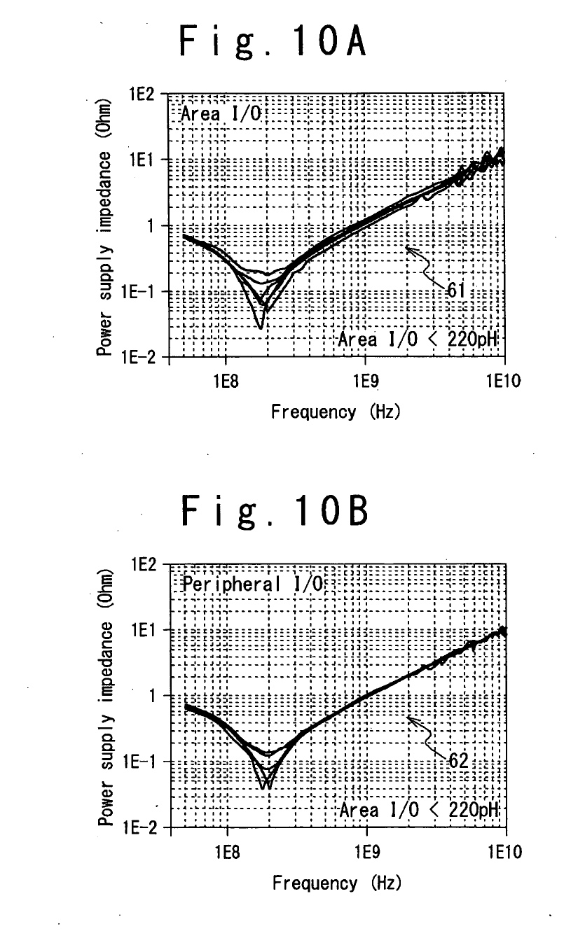

FIG. 10A shows a measurement result of the impedance of the area power supply vias 44 in the semiconductor apparatus 1 according to the present embodiment. The measurement result 61 shows the impedance variation of the area power supply vias 44 lower than that of the measurement results 161 and 162 shown in FIGS. 4A and 4B. FIG. 10B shows a measurement result of the impedance of the peripheral power supply via 41 in the semiconductor apparatus 1 according to the present embodiment. The measurement result 62 shows the impedance variation of the peripheral power supply via 41 lower than that of the measurement results 161 and 162 shown in FIGS. 4A and 4B. The measurement result 61 and the measurement result 62 shows that the impedance of the peripheral power supply via 41 and the impedance of the area power supply via 44 are approximately the same and that the impedance variation of the peripheral power supply via 41 and the impedance variation of the area power supply via 44 are both small. That is, the measurement result 61 and the measurement result 62 shows that the semiconductor apparatus 1 according to the embedment of the present invention reduces the power supply noise due to the area power supply vias 44 much more than the semiconductor apparatus shown in FIGS. 1 to 3.

Incidentally, in the semiconductor apparatus 1 according to the present invention, the package substrate 2 may further include area ground electrodes in the area I/O region 12. The area ground electrodes are arranged on an area ground region provided between the area signal region 30 and the area power supply region 29 in line. The area ground electrodes are electrically connected to the area ground vias 45. The semiconductor apparatus, even including the area ground electrodes, similarly to the semiconductor apparatus as shown in the above embodiment, obtains the following effects that the power supply vias 44 and the grid pattern have the strong mutual impedance, the effective impedance of the area power supply is drastically decreased, the power supply noise caused by the area power supply vias 44 is reduced, and the routing space for the multi-signal system is sufficiently secured. That is, the technique of the present invention is also applicable to the semiconductor apparatus including the above-mentioned area ground electrodes.

Further, the above embodiment shows the example that the grid ground plane 51 is electrically insulated from the area power supply vias 44 and surrounds each of the area power supply vias 44. However, even if the relation between the power supply and the ground is opposite to the above-mentioned embodiment, similar effects are obtained. Specifically, in FIGS. 7 and 8, grid power supply plane (51) is electrically insulated from area ground vias (44) and surrounds each of the area ground vias (44). In this case, apart of the grid power supply plane (51) is arranged between adjacent two of the area ground vias (44). In addition, a part of the grid power supply plane (51) is arranged between each area ground via (44) and each area signal via (43). Further, the grid power supply plane (51) is electrically insulated from an inside ground plane (35). The grid power supply plane (51) is electrically connected to a power supply plane (33) through area power supply vias (45). The area signal vias (43) are arranged adjacently to each other without passing through the gird power supply planes (51).

Further, the relation between the power supply and the ground may be changed in each wiring layer. That is, it is possible that the grid ground plane surrounds the area power supply vias in one wiring layer, and the grid power supply plane surrounds the area ground bias in another layer. The configuration above also gives the effects similar to the above-mentioned embodiment.

It is apparent that the present invention is not limited to the above embodiment, but may be modified and changed without departing from the scope and concept of the invention.

Although the present invention has been described above in connection with several exemplary embodiments thereof, it would be apparent to those skilled in the art that those exemplary embodiments are provided solely for illustrating the present invention, and should not be relied upon to construe the appended claims in a limiting sense.

What is claimed is:

1. A package substrate comprising:
a plurality of electrodes configured to be electrically connected to a semiconductor chip;
a plurality of wiring layers configured to be stacked; and
a plurality of vias configured to electrically connect a plurality of planes formed in said plurality of wiring layers,
wherein a power supply via included in said plurality of vias electrically connects a power supply plane included in said plurality of planes to a power supply electrode included in said plurality of electrodes, said power supply plane being supplied with a power supply voltage,
wherein a passing wiring layer included in said plurality of wiring layers, through which said power supply via passes, includes:
grid ground planes configured to surround said power supply via,
wherein said grid ground planes are electrically connected to a ground plane included in said plurality of planes through a ground via included in said plurality of vias, said ground plane being grounded.

2. The package substrate according to claim 1, wherein said plurality of vias includes:
a plurality of signal vias, each configured to transmit an electric signal,
wherein said plurality of signal vias is arranged adjacently to each other without through said grid ground planes.

3. The package substrate according to claim 2, wherein said passing wiring layer includes:
a signal plane configured to transmit said electric signal and be included in said plurality of planes,
wherein said each signal via is electrically connected to said signal plane.

4. The package substrate according to claim 2, wherein said power supply electrode is arranged on the center side of said package substrate as compared with a signal electrode included in said plurality of electrodes, to which said electric signal is transmitted.

5. A package substrate comprising:
a plurality of electrodes configured to be electrically connected to a semiconductor chip;
a plurality of wiring layers configured to be stacked; and
a plurality of vias configured to electrically connect a plurality of planes formed in said plurality of wiring layers,
wherein a ground via included in said plurality of vias electrically connects a ground plane included in said plurality of planes to a ground electrode included in said plurality of electrodes, said ground plane being grounded,
wherein a passing wiring layer included in said plurality of wiring layers, through which said ground via passes, includes:
grid power supply planes configured to surround said ground via,
wherein said grid power supply planes are electrically connected to a power supply plane included in said plurality of planes through a power supply via included in said plurality of vias, said power supply plane being supplied with a power supply voltage.

6. The package substrate according to claim 5, wherein said plurality of vias includes:
a plurality of signal vias, each configured to transmit an electric signal,
wherein said plurality of signal vias is arranged adjacently to each other without through said grid power supply planes.

7. A semiconductor apparatus comprising:
a semiconductor chip; and
a package substrate configured to be electrically connected to said semiconductor chip,
wherein said package substrate includes:
a plurality of electrodes configured to be electrically connected to said semiconductor chip;
a plurality of wiring layers configured to be stacked; and
a plurality of vias configured to electrically connect a plurality of planes formed in said plurality of wiring layers,
wherein a power supply via included in said plurality of vias electrically connects a power supply plane included in said plurality of planes to a power supply electrode included in said plurality of electrodes, said power supply plane being supplied with a power supply voltage,
wherein a passing wiring layer included in said plurality of wiring layers, through which said power supply via passes, includes:
grid ground planes configured to surround said power supply via,
wherein said grid ground planes are electrically connected to a ground plane included in said plurality of planes through a ground via included in said plurality of vias, said ground plane being grounded.

8. The semiconductor apparatus according to claim 7, wherein said plurality of vias includes:
a plurality of signal vias, each configured to transmit an electric signal,
wherein said plurality of signal vias is arranged adjacently to each other without through said grid ground planes.

9. The semiconductor apparatus according to claim 8, wherein said passing wiring layer includes:
a signal plane configured to transmit said electric signal and be included in said plurality of planes,
wherein said each signal via is electrically connected to said signal plane.

10. The semiconductor apparatus according to claim 8, wherein said power supply electrode is arranged on the center side of said package substrate as compared with a signal electrode included in said plurality of electrodes, to which said electric signal is transmitted.

11. A semiconductor apparatus comprising:
a semiconductor chip; and
a package substrate configured to be electrically connected to said semiconductor chip,
wherein said package substrate includes:
a plurality of electrodes configured to be electrically connected to said semiconductor chip;
a plurality of wiring layers configured to be stacked; and
a plurality of vias configured to electrically connect a plurality of planes formed in said plurality of wiring layers,
wherein a ground via included in said plurality of vias electrically connects a ground plane included in said plurality of planes to a ground electrode included in said plurality of electrodes, said ground plane being grounded,
wherein a passing wiring layer included in said plurality of wiring layers, through which said ground via passes, includes:
grid power supply planes configured to surround said ground via,
wherein said grid power supply planes are electrically connected to a power supply plane included in said plurality of planes through a power supply via included in said plurality of vias, said power supply plane being supplied with a power supply voltage.

12. The semiconductor apparatus according to claim 11, wherein said plurality of vias includes:
a plurality of signal vias, each configured to transmit an electric signal,
wherein said plurality of signal vias is arranged adjacently to each other without through said grid power supply planes.
